(19) United States
(12) Patent Application Publication
(10) Pub. No.: US 2011/0275221 A1
(43) Pub. Date: Nov. 10, 2011

(54) METHOD FOR TREATMENT SUBSTRATES AND TREATMENT COMPOSITION FOR SAID METHOD

(75) Inventor: Herbert SCHIER, VILLACH (AT)

(73) Assignee: LAM RESEARCH AG, VILLACH (AT)

(21) Appl. No.: 12/776,110

(22) Filed: May 7, 2010

(51) Int. Cl. H01L 21/467; C09K 13/04; C23F 1/00

(52) U.S. Cl. 438/745; 216/83; 252/79.2; 257/E21.486

(57) ABSTRACT

A mixture of perhalogenic acid and sulfuric acid is unexpectedly stable at high temperatures and is effective in stripping photoresists, including difficult to treat ion-implanted photoresists, with short processing times. In use, no decomposition of the mixture is observed up to a temperature of 145° C. In the mixture, the sulfuric acid is highly purified and has a concentration of 96 wt % or greater. The perhalogenic acid is preferably H₅IO₆.

### BACKGROUND OF THE INVENTION

1. Field of the Invention

The invention relates to acid compositions for treatment of substrates, and methods for treating substrates using such compositions.

2. Description of Related Art

Semiconductor processing with photoresists, including ebeam resists, is in widespread use despite some attendant problems. These include the difficulty in removal or stripping of the resists. Some photoresists are highly implanted, e.g., at ion doses in excess of 10¹⁵ atoms/cm², and at energies of implantation greater than 20 keV, and as much as 40 keV or more. Such implanted resists cannot be fully removed by conventional substrate treatment processes, and in some cases cannot be even partially removed.

Depending on the level of implantation energy and the type of dopant (boron, arsenic, etc.) many photoresists and their residues are stripped by SPM (sulfuric peroxide mix), SOM (sulfuric ozone mix) or, alternatively, by organic solvents; however, these techniques did not give a satisfactory result for all resists or were simply unable to remove residues at all.

U.S. Published Patent Application No. 2009/0281016 describes compositions including sulfuric acid and periodic acid, and their use in stripping ion-implanted photoresist. The compositions in some embodiments may include water, although the content thereof is preferably at a minimum. Although mention is made of wider process temperature ranges, in practice the mixtures were used at temperatures in a range of 60 to 95° C., consistent with the conventional belief that mixtures of periodic acid and strong mineral acid should not be heated to temperatures at which the mixture is freed of water due to risk of explosion or excessive release of heat.

### SUMMARY OF THE INVENTION

The present inventor has surprisingly discovered that aqueous solutions of perhalogenic acid can be safely mixed with concentrated sulfuric acid or even oleum and utilized at process temperatures in the range of 110° C. to 145° C. without decomposition or explosion of the composition.

Thus, one aspect of the present invention is a method of stripping photoresist that includes treating the photoresist with a mixture of sulfuric acid and perhalogenic acid, with the mixture being heated to a temperature in the range of 110° C. to 145° C.

Another surprising discovery associated with the present method is that the mixture of sulfuric acid and perhalogenic acid when used at the temperatures described above is capable of stripping even highly doped resist layers in much shorter processing times than are described in the prior art, with those time being 15 minutes or less, preferably ten minutes or less, more preferably five minutes or less and most preferably four minutes or less. Preferred ranges of processing times are from 30 seconds to 15 minutes, preferably one to ten minutes, more preferably one to five minutes and most preferably 90 seconds to four minutes.

Another aspect of the present invention is a stable mixture of sulfuric acid and perhalogenic acid, wherein the temperature of the mixture is in the range of 110° C. to 145° C.

A still further aspect of the invention is a method of making a composition for stripping photoresist, comprising dissolving perhalogenic acid in water to make an aqueous solution of perhalogenic acid, combining the aqueous solution of perhalogenic acid with sulfuric acid to form a treatment liquid, and heating the treatment liquid to a temperature in the range of 110° C. to 145° C.

The following detailed description of embodiments will further illustrate the invention but should not be viewed as limiting beyond the wording employed in the accompanying claims.

### BRIEF DESCRIPTION OF THE DRAWING FIGURES

FIG. 1 shows electron photomicrographs demonstrating the effectiveness of photoresist removal.

### DETAILED DESCRIPTION OF PREFERRED EMBODIMENTS

All percentages are weight percentages unless indicated otherwise.

Strong oxidizing agents (H₅IO₆, HClO₄, etc.) are added to 96% (or more concentrated 100%, oleum) sulfuric acid functioning as superacidic inorganic, oxidation stable solvent.

It was surprisingly discovered that perhalogenic acid can be safely mixed with concentrated sulfuric acid or even oleum without explosion or excessive release of heat, even at temperatures at which water would be expected to be freed from the mixture. The presence of water had conventionally been considered as attenuating the explosive properties of, e.g., HClO₄ or H₅IO₆. It had been previously assumed that it was inadvisable to heat up such concentrated mixtures to avoid explosions/decompositions, consistent with the experiments conducted in U.S. Published Patent Application No. 2009/0281016 discussed above.

The perhalogenic acid is preferably periodic acid, which may take the form of HIO₄ or H₅IO₆. Periodic acid is a strong oxidizing agent. In dilute solution, periodic acid exists as the ions H⁺ and IO₄⁻. When more concentrated, orthoperiodic acid, H₅IO₆, is formed. This can also be obtained as a crystalline solid. Further heating gives diiodine pentoxide (I₂O₅) and oxygen (according to eq. I).

2H₅IO₆=I₂O₅+5H₂O+O₂ eq. I

The anhydride diiodine heptoxide does not exist in nature but can be formed synthetically.

As used herein the term periodic acid encompasses both HIO₄ and H₅IO₆.

Of the raw materials, sulfuric acid is sold or used commercially in different concentrations, including technical (78% to 93%) and other grades (96%, 98-99%, and 100%). Impurities include metals such as iron, copper, zinc, arsenic, lead, mercury and selenium, sulfurous acid (as SO₂), nitrates and chlorides.

However, high purity sulfuric acid is produced for the semiconductor industry. For example, U.S. Pat. No. 6,740,302 (Hostalek et al.) teaches a process to produce sulfuric acid with an SO₂ content below 10 ppm. Commercially available semiconductor grade sulfuric acid includes PURANAL from Honeywell.

Periodic acid is available as a 50% solution or at 99.99% purity. Periodic acid can also be in the form of a white crystalline solid. In the present invention an aqueous solution of 45-65 wt % periodic acid (calculated as H₅IO₆) is preferred.

Reagent grade periodic acid has a higher level of impurities than semiconductor grade H₂SO₄. For example, 99.99% H₅IO₆ has 0.01% other halogens, 0.003% Fe and ppm metals impurities, which can include 3 ppm Al, 3 ppm Cu, 3 ppm Li, 3 ppm K, 3 ppm Na, 3 ppm Ca, 3 ppm Au, 3 ppm Mg, 3 ppm Zn, 3 ppm Cr, 3 ppm Pb, 3 ppm Ni and 3 ppm Ag.

The relative proportions of sulfuric acid and perhalogenic acid are preferably in the range of 1/100 to 1/5, the ratio being weight/weight of perhalogenic acid to sulfuric acid, calculated as H₅IO₆ and H₂SO₄.

A mitigating factor allowing one to obtain a stable mixture of H₂SO₄ and H₅IO₆ may arise from the fact that H₅IO₆ is a strong oxidizing reagent and the impurities therein are thus completely oxidized. When combined with the highly pure sulfuric acid, there is no significant amount of material (e.g., 160 ppt or less of Fe) capable of forming an instability inducing redox couple (such as Fe⁺⁺/Fe⁺⁺⁺). The mixture of the two acids is thus unexpectedly stable at elevated temperatures in the range of 110° C. to 145° C.

Similarly, the 10 ppm or less of SO₂ in high purity H₂SO₄ may mitigate or inhibit any SO₂/SO₄ (S⁺⁴/S⁺⁶) redox couple.

The molar concentration of the oxidizer (perhalogenic acid) is rather low, and it is therefore contemplated to use a reoxidization by ozone in order to recycle the stripping composition.

Also, it is possible to further modify to mixture in order to have improved properties, such as reducing metal corrosion. Still further, control of the water content can reduce metal corrosion.

Proportionally, the sulfuric acid and perhalogenic acid may be present in the mixture in relative proportions of 1/100 to 1/5, expressed as weight/weight of perhalogenic acid to sulfuric acid, calculated as H₅IO₆ and H₂SO₄. Also, the sulfuric acid and perhalogenic acid may be present in the mixture in relative proportions of 1/10, expressed as weight/weight of perhalogenic acid to sulfuric acid, calculated as H₅IO₆ and H₂SO₄.

Treatment time, i.e., the time that the stripping composition is maintained in contact with the surface to be cleaned, may be from 30 seconds to 15 minutes in, e.g., an apparatus for single wafer wet processing. The treatment time is preferably one to ten minutes, more preferably one to five minutes and most preferably 90 seconds to four minutes. The semiconductor wafer may be treated with ion-implanted photoresist.

The treatment mixture may be manufactured by mixing an aqueous solution of perhalogenic acid with concentrated sulfuric acid to form an initial mixture, and heating the initial mixture to a temperature in a range of 110° C. to 145° C.

In use, periodic acid is dissolved in water to about 60 wt % periodic acid, and the resulting aqueous solution is added to about 96% by weight of concentrated sulfuric acid. The resulting mixture is heated up to the corresponding process temperature in a range from 110° C. to 145° C. More specifically, about 15 liters of sulfuric are filled into a mixing tank system in a SP 305, followed by addition of about 2.5 liters of about 60 wt % H₅IO₆ in DI (deionized water). The process temperature is increased to 110° C. and then to 130° C., and no decomposition is observed. The liquid is supplied, e.g., sprayed, at a flow rate in the range of 0.5 to 5.0 l/min, preferably 1.0 to 3.0 l/min and most preferably 1.5 l/min through a nozzle onto a spinning chuck where a workpiece (a semiconductor wafer) has been mounted. Preferably, the method is performed in an apparatus for single wafer wet processing of semiconductor wafers.

Upon heating the processing liquid to 145° C. no decomposition took place, and the performance remained constant. However, at 150° C. strong outgassing occurred. Although the reason for this has not been established with certainty, it is believed to be the result of loss of water from the lattice, i.e., decomposition of perhalogenic acid.

Additional oxidizing agents may also be included in the mixture. These can include gaseous infusions of oxygen or ozone. Oxidizing agents such as permanganate, nitrate, ceric systems (for example ceric ammonium nitrate), perchlorate, hypochlorite, osmium tetroxide and/or their acids can be added.

When using the treatment fluid according to the invention at a temperature in the range of 110° C. to 145° C. the dwell time of the treatment fluid on a 300 mm diameter semiconductor wafer is preferably 30 sec to 15 minutes, preferably one to ten minutes, more preferably one to five minutes and most preferably 90 seconds to four minutes, and is thus much shorter than described in U.S. Published Patent Application No. 2009/0281016 discussed above.

### EXPERIMENTAL

Tests were performed on a single wafer processor Lam SP 305.

First the tool was manually rinsed with sulfuric acid, emptied and refilled with 15 liters of 96% by weight of sulfuric acid. Solid H₅IO₆ was mixed with deionized water to a concentration of 60% by weight (2.5 liter) and added to the sulfuric acid. The mix attained a temperature of approximately 60-70° C. and was further heated to 110° C. Pieces were run at this temperature. For other tests the process temperature was set to 130° C. Etch rates were also determined for tungsten and titanium nitride.

In a second attempt this mix was removed and the system refilled with 15 liters 96% sulfuric acid and 15 liters 60% periodic acid. This mixture corresponds more to the calculated percentage, as there are 6 liters dead volume (=water) remaining in that system. Etch rates with this formulation showed a superior performance.

At 145° C. bubbling (believed to be O₂ formation according to eq. I) started, but without formation of a yellow precipitate or discoloration, yet the mix was processible. At 150° C. the mix wasn't processible any more due to circulation problems.

The wafers utilized had photoresist layers with the following characteristics:

a) 1×10¹⁴ atoms/cm² As at 25 keV implantation energy

b) 4×10¹⁵ atoms/cm² BF₃ at 40 keV implantation energy

The results for the LAM SP 305 tests are set forth in Table 1. The concentrations (in brackets) are calculated from the mixes, whereby it was assumed that the free water fully reacts with free SO₃ (deriving from oleum) to H₂SO₄. The concentrations in the tables below reflect the calculated concentrations and do not reflect any dissociation that might occur.

TABLE 1

| Sample | Implant | Chemical | Process Time | Result |
|---|---|---|---|---|
| 21 | As 3E15 | H₂SO₄(96%) − H₅IO₆(50%) + Oleum | 120 s @125° C. | 99% clean |
| | @30 keV | H₂SO₄ (65% SO₃ sat.) 5:1:6 = mix 2 | | |
| | | (water concentration: 0%; H₅IO₆— | | |
| | | concentration: 3.3%; SO₃— | | |
| | | concentration: 8.7%; H₂SO₄— | | |
| | | concentration: 88%) | | |
| 22 | As 3E15 | HNO₃(69%) + H₂SO₄ (96%) + Oleum | 120 s @95° C. | 80% clean |
| | @30 keV | H₂SO₄ (65% SO₃ sat.) 1:1:0.5 | | |
| | | (water concentration: 8.5%) | | |
| 23 | As 3E15 | H₂SO₄ (96%) − H₅IO₆ (50%) 5:1 = | 120 s @110° C. | 95% clean |
| | @30 keV | mix 1 (water concentration: 11.2%; | | |
| | | H₅IO₆— concentration: 7.8% SO₃— | | |
| | | concentration: 0%; H₂SO₄— | | |
| | | concentration: 81%) | | |
| 24 | As 3E15 | mix 1 | 120 s @90° C. | Not clean |
| | @30 keV | | | |
| 25 | As 3E15 | mix 1 | 120 s @95° C. | Not clean |
| | @30 keV | | | |
| 26 | As 3E15 | HNO₃(69%) + H₂SO₄ (96%) + Oleum | 120 s @105° C. | Not clean |
| | @30 keV | H₂SO₄ (65% SO₃ sat.) 5:2:5 (water | | |
| | | concentration: 4.3%) | | |
| 27 | As 3E15 | H₂SO₄ (96%) − H₅IO₆ (50%) + Oleum | 120 s @112° C. | 80% clean |
| | @30 keV | H₂SO₄ (65% SO₃ sat.) 5:2:5 = mix 5 | | |
| | | (water concentration: 2.8%; H₅IO₆— | | |
| | | concentration: 7.5%; SO₃— | | |
| | | concentration: 0%; H₂SO₄— | | |
| | | concentration: 89.6%) | | |
| 28 | As 3E15 | H₂SO₄ (96%) − H₅IO₆ (50%) + Oleum | 120 s @136° C. | 99% clean |
| | @30 keV | H₂SO₄ (65% SO₃ sat.) 5:2:6 (water | | |
| | | concentration: 1.4%; H₅IO₆— | | |
| | | concentration: 6.9%; SO₃— | | |
| | | concentration: 0%; H₂SO₄— | | |
| | | concentration: 89.6%) | | |
| 29 | As 3E15 | mix 1 | 120 s @90° C. | Not clean |
| | @30 keV | | | |
| 30 | As 3E15 | mix 1 | 120 s @120° C. | 99% clean |
| | @30 keV | | | |
| 31 | As 3E15 | mix 1 | 120 s - mixed at | 99% clean |
| | @30 keV | | 90° C. and heated | |
| | | | up to 120° C. | |

Screening tests were also performed using test coupons. For beaker tests, in order to create a comparable mix, a 50% solution of H₅IO₆ in deionized water and 96% H₂SO₄ were combined at a ratio of 1:5. Specifically, in a beaker 100 ml of 96% sulfuric acid were added to 20 ml 50% H₅IO₆. An increase of temperature due to solvation followed at which a test coupon was submerged in the solution for 2 minutes. Two minutes was considered an appropriate screening interval for predicting performance in single wafer processors. The tests were performed for the following type of wafer: Arsenic (As) implantation dose 3×10¹⁵, 30 keV implantation energy.

The processing conditions for the coupon tests are set forth in Table 2.

TABLE 2

| Test no. | composition | T | | time |
|---|---|---|---|---|
| 4-1/7-1: | H₅IO₆ (50%) were mixed with H₂SO₄ (96%) ratio 1:5 = mix 1 | 80° | C. | 2 min |
| | (water concentration: 11.2%; H₅IO₆— concentration: 7.8%; | | | |
| | SO₃— concentration: 0%; H₂SO₄— concentration: 81%) | | | |
| 4-2: | mix 1 was mixed with Oleum (65% SO₃ saturation) 1:1 = mix 2 | 125° | C. | 2 min |
| | (water concentration: 0%; H₅IO₆— concentration: 3.3%; SO₃— | | | |
| | concentration: 8.7%; H₂SO₄— concentration: 88%) | | | |
| 4-3: | mix 2 | 40° | C. | 2 min |
| 7-2 | mix 1 was mixed with Oleum (65%SO₃ saturation) 1:2.5 = mix 3 | 110° | C. | 2 min |
| | (water concentration: 0%; H₅IO₆— concentration: 1.5%; SO₃— | | | |
| | concentration: 23.8%; H₂SO₄— concentration: 89.6%) | | | |
| 7-3 | mix 3 | 90° | C. | 2 min |
| 7-4 | mix 3 | 70° | C. | 2 min |
| 8-3 | H₅IO₆ (50%) were mixed with H₂SO₄ (100%) ratio 1:5 = mix 4 | 90° | C. | 2 min |
| | (water concentration: 7.8%; H₅IO₆— concentration: 7.8%; SO₃— | | | |
| | concentration: 0%; H₂SO₄— concentration: 84.4%) | | | |
| 8-2 | mix 4 | 70° | C. | 2 min |
| 9-1 | H₅IO₆ (50%) were immediately mixed with H₂SO₄ (96%) and | 136° | C. | 2 min |
| | Oleum (65% SO₃ saturation) ratio 2:5:5 = mix 5 | | | |
| | (water concentration: 2.8%; H₅IO₆— concentration: 7.5%; SO₃— | | | |
| | concentration 0%; SO₃— concentration: 0%; H₂SO₄— concentration: | | | |
| | 89.6%) | | | |
| 9-2 | mix 5 | 112° | C. | 1 min |
| 9-3 | mix 5 | 105° | C. | 30 s |
| 9-4 | mix 5 | 75° | C. | 2 min |

Tests were also performed for the following type of wafers: Arsenic doped 3×10¹⁵ atoms/cm² with 30 KeV. The processing conditions are in Table 3.

TABLE 3

| Test no. | composition | T | time |
|---|---|---|---|
| 1-1 | H₅IO₆ (50%) were mixed with H₂SO₄ (100%) ratio 1:5 = mix 4 | 90° C. | 2 min |
| | (water concentration: 7.8%; H₅IO₆— concentration: 7.8%; SO₃— | | |
| | concentration: 0%; H₂SO₄— concentration: 84.4%) | | |
| 1-2 | preheated H₅IO₆ (50%) (65° C.) were mixed with preheated (55° C.) | 125° C. | 1 min |
| | H₂SO₄ (100%) ratio 1:5 = mix 6 (water concentration: 7.8%; H₅IO₆— | | |
| | concentration: 7.8%; SO₃— concentration: 0%; H₂SO₄— concentration: | | |
| | 84.4%) | | |
| 1-3 | preheated H₅IO₆ (50%) (65° C.) were mixed with preheated (55° C.) | 120° C. | 2 min |
| | H₂SO₄ (100%) ratio 1:5 and temperature maintained by an oil bath = | | |
| | mix 7 (water concentration: 7.8%; H₅IO₆— concentration: 7.8%; SO₃— | | |
| | concentration: 0%; H₂SO₄— concentration: 84.4%) | | |

The results were evaluated using a scanning electron microscope (SEM). The results are set forth in Table 4.

TABLE 4

| No | mix | temperature | | time | result |
|---|---|---|---|---|---|
| 1-1 | 4 | 90° | C. | 2 min | crust and resist displaced, redeposition of dissolved |
| | | | | | material (flakes) |
| 1-2 | 6 | 125° | C. | 1 min | complete removal |
| 1-3 | 7 | 120° | C. | 2 min | complete removal |
| 4-1/7-1 | 1 | 80° | C. | 2 min | resist mostly removed, displaced, but some residue |
| | | | | | left, still |
| 4-2 | 2 | 125° | C. | 2 min | crust is completely removed |
| 4-3 | 2 | 40° | C. | 2 min | attack but crust is just displaced in large debris |
| 7-2 | 3 | 110° | C. | 2 min | few debris remain, bulk crust is removed |
| 7-3 | 3 | 90° | C. | 2 min | crust attacked, but not removed |
| 7-4 | 3 | 70° | C. | 2 min | no cleaning, slight attack of the crust |
| 8-3 | 4 | 90° | C. | 2 min | crust and resist displaced, redeposition of dissolved |
| | | | | | material (flakes) |
| 8-2 | 4 | 70° | C. | 2 min | no cleaning, slight attack of the crust |
| 9-1 | 5 | 136° | C. | 2 min | complete removal of resist and crust |
| 9-2 | 5 | 112° | C. | 1 min | some displaced debris remaining onto the wafer |
| | | | | | surface |
| 9-3 | 5 | 105° | C. | 30 s | resist & crust attack, but not removed |
| 9-4 | 5 | 75° | C. | 2 min | only slight attack of the resist |

The results showed that that the samples implanted with As at 25 keV and 1×10¹⁴ atoms/cm² were clear of photoresist at 120 seconds at 120° C., and the 25 keV 1×10¹⁴ atoms/cm² As samples were clear of photoresist at 60 seconds at 130° C.

The 40 keV 4×10¹⁵ atoms/cm² BF₃ samples were clear of photoresist by 360 seconds at 110° C., and were clear of photoresist by 300 seconds at 130° C. At 145° C. the 40 keV 4×10¹⁵ atoms/cm² BF₃ samples were not clear of photoresist at 240 seconds, where the failure to remove photoresist may be due to a breakdown in the chemistry at 150° C. as outgassing was observed.

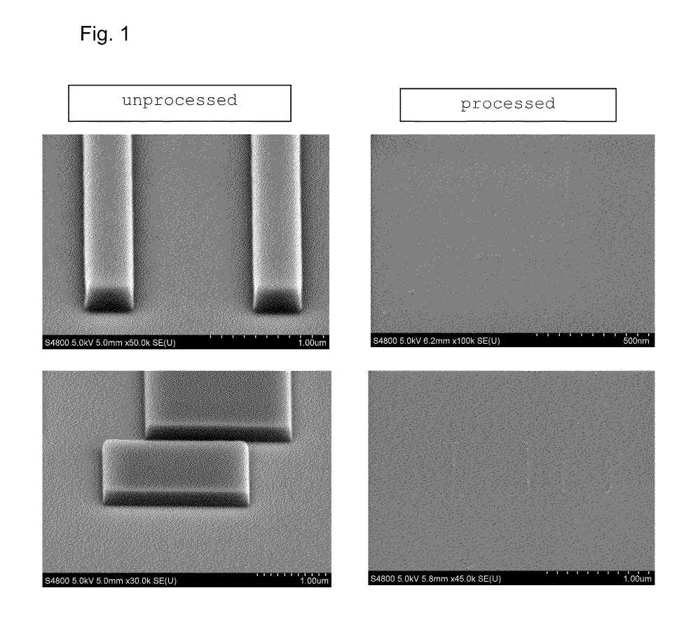

FIG. 1 shows electron photomicrographs demonstrating the effectiveness and thoroughness of the stripping, where the processing leaves virtually no residue.

The etch rate performed on titanium nitride layers and tungsten layers showed that the lower the water concentration is, the lower the corrosion (water concentration in mix vs. water-free medium).

Water reduction limits corrosion. With regard to process time, a time exceeding about four minutes adversely contributes to corrosion.

The SEM and microscopic pictures also showed that the high temperatures and shear flow rates (approximately 1.5 l/min) prevailing in the single wafer processor considerably assisted the removal from the wafer of the crust and debris liberated by the stripping solution.

The mix can be recycled and freed from impurities/residues by a filter, as not all debris will be dissolved. This is expected to provide a prolonged bath lifetime over batch processes.

Comparative results are obtained from Examples 1-6 of U.S. Published Patent Application No. 2009/0281016.

Comparative Example 1 used mixtures of sulfuric acid and periodic acid, at concentrations of 5-15% periodic acid to remove high-density implanted resist at temperatures between 60 and 95° C. and reaction times of 30-60 minutes, depending on type of implant, dose and energy. For example, solutions of 4.75 wt % and 9.1 wt % periodic acid in concentrated sulfuric acid cleaned a test pattern of implanted resist (2×10¹⁵ atoms/cm⁻² As, 20 keV) in 30 minutes at 60° C. The process tolerates a small amount of water, e.g. 2 g periodic acid, 1 g water, and 19 g concentrated (about 96%) sulfuric acid.

Comparative Example 2 used a large batch of a 10% periodic acid in concentrated sulfuric acid solution, separated into 22 different containers and heated to 80° C. These solutions were tested at various intervals for cleaning ability using 2×10¹⁵ atoms/cm⁻² As 20 keV wafers.

Comparative Example 3 was performed on wafers using a mask and included UV 110 G positive 248 nm resist and combined ion-implants. Resist lines typical of 90 nm node patterns and slightly beyond, down to 225 nm width and 400 nm pitch were evaluated. In the case of heavier implants (e.g., 4×10¹⁵ atoms/cm⁻² BF²⁺ and 3.5×10¹⁵ atoms/cm⁻² As), significant resist residues were redeposited on the wafer.

Comparative Example 4 entailed the addition of potassium permanganate to the 5% periodic acid-concentrated sulfuric acid mixture in order to speed up the reaction. The concentrations of KMnO₄ added were 49, 220, and 1000 ppm, and the test samples implanted with 1×10¹⁶ atoms/cm⁻² As at 20 keV.

Comparative Example 5 was to determine whether periodic acid and KMnO₄ pose a wafer contamination risk. Blanket silicon wafers were treated for 30 min at 90° C. in (a) a 5% periodic acid-concentrated sulfuric mix or (b) the formulation in (a) plus 220 ppm added KMnO₄. The wafers were then rinsed in water or an aqueous cleaning solution, and examined by Total Reflection X-ray Fluorescence Spectroscopy (TXRF).

Comparative Example 6 were a series of experiments using a batch of wafers developed using a proprietary mask where the wafers included positive 248 nm resist and combined ion-implants (3×10¹⁴ atoms/cm⁻² Ge at 15 KeV and 3.5×10¹⁵ atoms/cm⁻² As at 15 KeV). The wafers were immersed in Formulations A-C, as described below, at 60° C. for 30 minutes, rinsed, and optical micrographs obtained. Formulation A: 1 wt % ammonium persulfate, 99 wt % SPM (sulfuric acid/hydrogen peroxide mixture) having a 4:1 v/v ratio. Formulation B: 5 wt % ammonium persulfate, 95 wt % SPM having a 4:1 v/v ratio. Formulation C: 15 wt % ammonium persulfate, 85 wt % SPM having a 4:1 v/v ratio.

The results are in Table 5 below.

TABLE 5

| | | | required | | implantation | | implantation | type of | conc. | | |
|---|---|---|---|---|---|---|---|---|---|---|---|
| sample | Temp. | | time | | energy | | concentration | implant | H₅IO₆ | | remarks |
| 1 | 60-95° | C. | 30-60 | min | | | | | | | 22 g (!) mix |
| | | | | | | | | | | | prepared |
| 1a | 60° | C. | 30 | min | 20 | keV | 2 × 10¹⁵ | As | 5 | resp. | clean |
| | | | | | | | | | 9 | wt % | |
| 1b | 80° | C. | 30 | min | 20 | keV | 5 × 10¹⁵ | As | 5 | resp. | clean |
| | | | | | | | | | 9 | wt % | |
| 1c | 80° | C. | 30 | min | 40 | keV | 1 × 10¹⁵ | As | 5 | resp. | clean |
| | | | | | | | | | 10 | wt % | |
| 1d | 80° | C. | 30 | min | 20 | keV | 5 × 10¹⁵ | As | 5 | resp. | clean |
| | | | | | | | | | 10 | w.-% | |
| 1e | 80° | C. | 30 | min | 20 | keV | 1 × 10¹⁶ | As | 5 | resp. | only partial |
| | | | | | | | | | 10 | wt % | cleaning |

| 2a | 80° | C. | 92 | h | | | | | 10% | no alteration |
|---|---|---|---|---|---|---|---|---|---|---|
| | | | | | | | | | | of chemistry |
| 2b | 80° | C. | 140 | h | | | | | 10% | yellow |
| | | | | | | | | | | precipitate |
| 2c | 60° | C. | 30 | min | 20 | keV | 2 × 10¹⁵ | As | 10% | complete |
| | | | | | | | | | | removal |
| 3a | 90° | C. | 30 | min | 90 | nm node | | | 5% | complete |
| 3b | 90° | C. | 30 | min | n.a. | | 4 × 10¹⁵ | BF²⁺ | 5% | redeposition |
| | | | | | | | | | | residues, |
| | | | | | | | | | | mere |
| | | | | | | | | | | suggestion |
| | | | | | | | | | | how to |
| | | | | | | | | | | remove (SC- |
| | | | | | | | | | | 1, geometry) |
| 3c | 90° | C. | 30 | min | n.a. | | 3.5 × 10¹⁵ | As | 5% | redeposition |
| | | | | | | | | | | residues, |
| | | | | | | | | | | mere |
| | | | | | | | | | | suggestion |
| | | | | | | | | | | how to |
| | | | | | | | | | | remove (SC- |
| | | | | | | | | | | 1, geometry) |
| 4a | n.a. | | n.a. | | 20 | keV | 1 × 10¹⁶ | As | 5% H₅IO₆ + | no complete |
| | | | | | | | | | 49 ppm | removal |
| | | | | | | | | | KMnO₄ | |
| 4b | n.a. | | n.a. | | 20 | keV | 1 × 10¹⁶ | As | 5% H₅IO₆ + | incomplete |
| | | | | | | | | | 220 ppm | removal |
| | | | | | | | | | KMnO₄ | |
| 4c | n.a. | | n.a. | | 20 | keV | 1 × 10¹⁶ | As | 5% H₅IO₆ + | incomplete |
| | | | | | | | | | 1000 ppm | removal |
| | | | | | | | | | KMnO₄ | |
| 5a | 90° | C. | 30 | min | blanket | | blanket | silicon | 5% H5_{I}O₆ + | SC-1 |
| | | | | | | | | wafers | 220 ppm | followed, |
| | | | | | | | | | KMnO₄ | contamination |
| | | | | | | | | | | test said |
| | | | | | | | | | | not having |
| | | | | | | | | | | spoiled the |
| | | | | | | | | | | wafer |
| 5b | 90° | C. | 30 | min | 15 | keV | 3.5 × 10¹⁵ | As | 0.2% in | complete |
| | | | | | | | | | conc. | removal |
| | | | | | | | | | H₂SO₄ | |
| 5c | 90° | C. | 30 | min | 40 | keV | 1 × 10¹⁶ | As | 0.2% in | incomplete |
| | | | | | | | | | conc. | removal |
| | | | | | | | | | H₂SO₄ | |
| 6a | 60° | C. | 30 | min | 15 | keV | 3 × 10¹⁴ | Ge | mix A, | 1 wt % |
| | | | | | | | | | SPM (4:1) | (NH₄)₂S₂O₈ |
| 6a | 60° | C. | 30 | min | 15 | keV | 3.5 × 10¹⁵ | As | mix A | no |
| | | | | | | | | | | information, |
| | | | | | | | | | | probably |
| | | | | | | | | | | incomplete |
| | | | | | | | | | | removal |
| 6b | 60° | C. | 30 | min | 15 | keV | 3 × 10¹⁴ | Ge | mix B SPM | 5 wt % |
| | | | | | | | | | (4:1) | (NH₄)₂S₂O₈ |
| 6b | 60° | C. | 30 | min | 15 | keV | 3.,5 × 10¹⁵ | As | mix B SPM | slight |
| | | | | | | | | | (4:1) | redeposition |
| 6c | 60° | C. | 30 | min | 15 | keV | 3 × 10¹⁴ | Ge | mix C SPM | 15 wt % |
| | | | | | | | | | (4:1) | (NH₄)₂S₂O₈ |
| 6c | 60° | C. | 30 | min | 15 | keV | 3.5 × 10¹⁵ | As | mix C | slight |
| | | | | | | | | | | redeposition |

As can be seen, in the lower temperature range of the comparative art there was incomplete removal, redeposition, precipitation and wafer spoilage. In contrast, the elevated temperatures of the technology of the present application achieve complete resist removal at reduced treatment times.

It is to be understood that the foregoing descriptions and specific embodiments shown herein are merely illustrative of the technology and the principles thereof, and that modifications and additions may be easily made by those skilled in the art without departing from the spirit and scope of the invention, which is therefore understood to be limited only by the scope of the appended claims.

What is claimed is:

1. A method for treating a substrate, comprising:
contacting the substrate with a mixture of sulfuric acid and perhalogenic acid, the mixture being at a temperature in the range of 110° C. to 145° C., for 15 minutes or less.

2. The method according to claim 1, wherein the perhalogenic acid is periodic acid (H₅IO₆).

3. The method according to claim 1, wherein the sulfuric acid is present at a range of 50-99.5 wt. % and perhalogenic acid is present in said mixture at a range of 0.1-10 wt. %, calculated as H₅IO₆ and H₂SO₄.

4. The method according to claim 3, wherein the sulfuric acid is present at a range of 70-99.5 wt. % and perhalogenic acid is present in said mixture at a range of 0.2-2 wt. %, calculated as H₅IO₆ and H₂SO₄.

5. The method according to claim 1, wherein the substrate is a semiconductor wafer in an apparatus for single wafer wet processing.

6. The method according to claim 5, wherein the semiconductor wafer comprises an ion-implanted photoresist.

7. The method according to claim 6, wherein the semiconductor wafer comprises an arsenic ion-implanted photoresist.

8. The method according to claim 6, wherein the semiconductor wafer comprises a boron ion-implanted photoresist.

9. The method according to claim 1, wherein the substrate is contacted with the mixture of sulfuric acid and perhalogenic acid for ten minutes or less.

10. The method according to claim 1, wherein the substrate is contacted with the mixture of sulfuric acid and perhalogenic acid for four minutes or less.

11. The method according to claim 1, wherein a water concentration of 0.5 up to 2 wt.-%

12. A composition for treating a substrate, comprising:
a stable mixture of sulfuric acid and perhalogenic acid, wherein the temperature of the mixture is in the range of 110° C. to 145° C.

13. The composition according to claim 12, wherein the perhalogenic acid is an aqueous solution of 45-65 weight % periodic acid (calculated as H₅IO₆).

14. The composition according to claim 12, wherein the sulfuric acid and perhalogenic acid are present in said mixture in relative proportions of 1/100 to 1/5, expressed as weight/weight of perhalogenic acid to sulfuric acid, calculated as H₅IO₆ and H₂SO₄.

15. The composition according to claim 14, wherein the sulfuric acid and perhalogenic acid are present in said mixture in relative proportions of 1/10, expressed as weight/weight of perhalogenic acid to sulfuric acid, calculated as H₅IO₆ and H₂SO₄.
